(19) United States
(12) Patent Application Publication
(10) Pub. No.: US 2022/0177677 A1
(43) Pub. Date: Jun. 9, 2022

(54) MULTICOMPONENT SYSTEM AND PROCESS FOR PRODUCING A MULTICOMPONENT SYSTEM, ESPECIALLY FOR USE IN MICROELECTRONICS

(71) Applicant: Sphera Technology GmbH, Munich (DE)

(72) Inventor: Janine-Melanie Potreck, Munich (DE)

(73) Assignee: Sphera Technology GmbH, Munich (DE)

(21) Appl. No.: 17/598,006

(22) PCT Filed: Mar. 24, 2020
(86) PCT No.: PCT/EP2020/058118

§ 371 Date: Sep. 24, 2021

(30) Foreign Application Priority Data
Mar. 25, 2019 (DE) 10 2019 107 633.1

(51) Int. Cl. C08K 9/08; H05K 1/09; H05K 3/00

(52) U.S. Cl. CPC C08K 9/08; H05K 1/09; C08K 2201/001; C08K 2201/011; C08K 2201/01; H05K 3/00

(57) ABSTRACT

A conductive multi-component system contains at least one first substance and at least one substrate, where the first substance is present in one or more portions of substance. At least one first portion of substance is formed with at least one first functional group and is provided with a first linker, and/or the substrate is formed with at least one second functional group and is provided with a second linker. The first functional group reacts via a predefined interaction with the second functional group and/or the substrate and bonds them together, and/or the second functional group reacts by virtue of a predefined interaction with the first functional group and/or the first substance and bonds them to one another. A portion of substance of the first substance is in the form of particles or in particles and is at least partially conductive. A process can produce an electrically conductive multi-component system.

The present invention relates to a multi-component system and a method for producing a multi-component system, in particular for microelectronic applications.

Multi-component systems are already known from the prior art.

US 2012/0107601 A1 further discloses a capsule system that responds to pressure and releases fluids accordingly.

Other capsule systems are known, for example, from WO 2017/192407 A1, U.S. Pat. No. 8,747,999 B2, WO 2017 042709 A1, WO 2016/049308 A1 and WO 2018/028058 A1.

US 2018/0062076 A1 discloses a method for forming a conductive layer with molecular components, wherein multiple conductive nanoparticles are linked together.

The functionalization of metallic nanoparticles is known, for example, from WO2015/103028A1, CA2712306C and U.S. Pat. No. 8,790,552 B2.

Puebla-Hellmann G., et al. (2018), “Metallic nanoparticle contacts for high-yield, ambient-stable molecular-monolayer devices”, Nature, Vol. 559) describes a method for using molecules for electronic applications using a self-assembled monolayer (SAM) sandwich architecture.

Thiol functionalizations are available, for example, from Kellon J. E., Young S. L., & Hutchison J. E. (2019), “Engineering the Nanoparticle-Electrode Interface”, Chemistry of Materials, 31(8), 2685-2701, further from Kubackova J., et al. (2014), “Sensitive surface-enhanced Raman spectroscopy (SERS) detection of organochlorine pesticides by alkyl dithiol-functionalized metal nanoparticles-induced plasmonic hot spots”, Analytical chemistry 87.1, 663-669, also from Ahonen P., Laaksonen T., Nykanen A., Ruokolainen J., & Kontturi K. (2006), “Formation of stable Ag-nanoparticle aggregates induced by dithiol cross-linking”, The Journal of Physical Chemistry B, 110(26), 12954-12958 and from Dong T. Y., Huang C., Chen C. P., & Lin M. C. (2007), “Molecular self-assembled monolayers of ruthenium (II)-terpyridine dithiol complex on gold electrode and nanoparticles”, Journal of Organometallic Chemistry, 692(23), 5147-5155 and from Hofmann, A., Schmiel, P., Stein, B., & Graf, C. (2011), “Controlled formation of gold nanoparticle dimers using multivalent thiol ligands”, Langmuir, 27(24), 15165-15175.

Solutions concerning selective conductivity are further known from U.S. Pat. Nos. 5,731,073, 5,498,467, EP 0 841 698, WO 2017/139654 A1, WO 2017/138483 A1, KR 101195732 B1 and US 2010/0327237 A1.

It is the object of the present invention to provide an electrically conductive multi-component system as well as a method for producing an electrically conductive multi-component system, in particular in that the amount of the individual components of multi-component systems and their arrangement can be controlled on the one hand to improve the efficiency of the reaction of the multi-component system and, on the other hand, to enable precise and accurately defined electrical conduction.

According to the invention, this object is solved by a multi-component system having the features of claim 1. Accordingly, a conductive multi-component system is provided with at least one first substance and at least one substrate, wherein

(a) the first substance is present in one or more portions of said substance,
b) the at least one first portion of substance is formed with at least one first functional group and provided with a first linker and/or wherein the substrate is formed with at least one second functional group and provided with a second linker,
c) the first functional group reacts via a predefined interaction with the second functional group and/or the substrate and binds them together and/or wherein the second functional group reacts via a predefined interaction with the first functional group and/or the first substance and binds them together,
(d) a portion of the first substance is present as a particle or in particles and is at least partially conductive.

The invention is based on the concept that at least one first substance and at least one substrate are spatially arranged in a defined manner relative to one another by the linkers and the link by the functional groups. Thus, it is now possible to arrange the first substance and the substrate in a defined ratio and at a defined distance. Through appropriate activation, conductivity can be specifically enabled in that region in which the first substance binds to the substrate. The conductivity can be generated very specifically and in a defined manner even in very small structures. In particular, it is conceivable to generate conductive compounds in the micrometer range or nanometer range or even smaller by means of the multi-component system, which are usually produced by bonding or soldering or gluing or the like. The at least one particle may in particular be a microparticle or a nanoparticle.

In particular, it may be provided that the conductivity of the portion of substance is an electrical conductivity and/or thermal conductivity and/or signal conductivity.

It is conceivable that the particle or particles are capable of self-assembly or self-alignment. In this case, the particles are capable of self-aligning with the substrate in a predetermined or predefined direction, such as a conductor path.

The self-assembly can be achieved, for example, by thiol groups (SAM surface, see also described below) and/or Janus.(nano)-particles, and/or patchy particles, and/or by magnetism (particle and surface magnetic) and/or via electrostatic interaction. Such interactions can be achieved, for example, by a positively charged surface, a negatively charged surface and/or via weak interactions and/or via chemical reaction(s) such as click chemistry (e.g. thiol-ene click chemistry), Michael reaction or the like.

Furthermore, it may be provided that the distance of the functional groups to the portion of substance and the substrate is determined by the respective linker.

The substrate can be a circuit board or a printed circuit board or a conductor path, for example in the field of semiconductor technology (a wafer (e.g. silicon wafer or silicone wafer) or chip). Particularly in the field of microelectronics, i.e., in the connection of conductive traces on boards or chip or 3D integration or the like, conductive connections at the correct location, which are durable, have higher electrical conductivity, exhibit fewer short circuits, and enable miniaturization, are of great benefit. By using the multi-component system, a conductive connection can be prepared on the substrate by firstly positioning the multi-component system. Position correction is also possible in this process. Thereafter, the multi-component system is activated (e.g., as described below) and the conductive connection is established.

If a (single) particle is used, then the conductive connection can be made, for example, between two conductor paths by the particle touching both conductor paths and then being fixed there accordingly by activation.

In a case where several particles are present, the particles touch each other, thus creating a “constant path” between two conductor paths. Accordingly, this also creates a conductive connection.

The activation releases the particles. Then, the particles independently arrange themselves at the intended location, e.g., by terminal thiol groups or conductive polymers or by Janus-(nano)-particles (so-called self-assembly). This process can also be supported, e.g., by magnetic fields and/or electric fields.

It may also be provided that the substrate is a second substance.

In particular, it may be provided that the functional group of the portions of the first substance and the functional group of the substrate specifically bind to each other.

In particular, it may also be provided that the functional group of the portions of substance selectively binds to metal surfaces, e.g. SAM surfaces (self-assembling monolayers).

The nanoparticle may, at least in part, consist of silver, gold and/or copper and/or composites and/or other metals or alloys thereof and/or other materials.

Moreover, it may be provided that the substrate is a surface, or has a surface. The surface may be, for example, a wafer, (micro)chip, flexible electronic component or a printed circuit board or the like. Moreover, it is conceivable that the surface is a conductive substrate. Furthermore, it is conceivable that the substrate is a substrate having conductor paths. For example, the conductor paths may be vapor deposited, printed or etched. Further, it is possible that the conductor paths are applied to the substrate using thin-film technology or other technology.

In particular, it may be provided that the size of the nanoparticles is smaller than the distance between the conductor paths.

It is also conceivable that the first linker is longer than the second linker or vice versa. This results in the advantage that, for example, the first substances take a larger or smaller distance from one another after corresponding bonding than the first substance and the substrate.

Alternatively, it is possible for both linkers to have the same length.

A linker can be any form of connection between a portion of substance and a functional group.

A linker may also be any type of direct connection between a portion of substance and/or a capsule and/or a substrate and a functional group.

Possible linkers include biopolymers, proteins, silk, polysaccharides, cellulose, starch, chitin, nucleic acid, synthetic polymers, homopolymers, DNA, halogens, polyethylenes, polypropylenes, polyvinyl chloride, polylactam, natural rubber, polyisoprene, copolymers, random copolymers, gradient copolymer, alternating copolymer, block copolymer, graft copolymers, arcylnitrile butadiene styrene (ABS), styrene-acrylonitrile (SAN), buthyl rubber, polymer blends, polymer alloy, inorganic polymers, polysiloxanes, polyphophazenes, polysilazanes, ceramics, basalt, isotactic polymers, syndiodactic polymers, atactic polymers, linear polymers, cross-linked polymers, elastomers, thermoplastic elastomers, thermosets, semi-crystalline linkers, thermoplastics, cis-trans polymers, conductive polymers, supramolecular polymers.

It is also conceivable that the functional groups are formed homogeneously or heterogeneously. It is conceivable, for example, that a substance and the associated functional groups are heterogeneous, i.e., that different functional groups can be used. This is desirable, for example, if it is desired to achieve that, for example, certain linkers are first provided with protective groups during manufacture and can be used to build specific bonds, for example first substance to first substance or also first substance to substrate (or also substrate to substrate). It is also conceivable that a first functional group enables binding of two portions of substance, and a second, different functional group enables binding of first substances to a substrate. It is also conceivable that a first functional group enables binding of portions of substances, and a second, different functional group enables changing the properties of the capsules, e.g. the biocompatibility, solubility, aggregation, or similar properties. It is also conceivable that heterogeneous functional groups enable a three- or multi-component system to be formed.

Instead of a protective group, it may alternatively be provided that two bonds are present, wherein a first bond binds capsules to each other and a second bond binds capsules or portions of substance or substances to a substrate, surface or fibers or the like.

However, it is also conceivable that all functional groups are formed homogeneously, i.e., identically. In the case of heterogeneous formation, it is also conceivable that this is combined with further properties or differences in the design of the linkers (e.g. length, angle, type of linker, etc.).

Furthermore, it is conceivable that a portion of substance of the first substance is arranged in a capsule, in particular a nanocapsule and/or microcapsule. The encapsulation makes it possible to provide a defined mass or a defined volume of the first substance for the conductive multi-component system. In a multi-capsule system or, for example, a two-component capsule system (2C capsule system), it is possible for the contents of the capsules to be bound to one another in a defined number and/or a defined ratio or number and spacing in separate compartments until the capsules are activated and thus their contents can react with one another or are forced to react with one another or mix if the capsules have the same contents. One or more portion of substance(s) of a substance is/are arranged or packaged in each capsule. It is also conceivable that a capsule contains several portions of substance. An arrangement of capsules with first substances (or also second or third substances) can also be referred to as a capsule complex and has approximately a function comparable to a (mini)-reaction flask, in which the reagents are mixed with each other after activation at a defined time point and the reaction of the substances with each other is initiated. Due to the large number of these capsule complexes, the mode of action is added up and there is a greater effect or the mixing and reaction of the substances is improved. Further advantages result from the better mixing of the individual substances or reaction components with each other and thus—compared to previous systems—a higher turnover can be achieved at lower material input.

Possible types of capsule include, for example, double capsules, multi-core capsules, capsules with cationic or anionic character, capsules with different shell material, Janus particles, patchy particles, porous capsules, capsules with multiple shells, capsules with metal nanoparticles, matrix capsules and/or hollow capsules, capsules with multiple layers of shell material (so-called multilayer microcapsules) and/or empty porous capsules (for example to encapsulate odors).

Furthermore, it may be provided that the capsules of the first substance have an identical size. This results in an adjustment of the ratio of the volumes of the first substance in relation to the substrate (or vice versa) and/or also in an adjustment of the activation behavior (if at least parts of the multi-component system can be activated).

It is also conceivable that at least parts of the multi-component system can be activated and the activation of the multi-component system is effected by at least one change in pressure, pH value, UV radiation, osmosis, temperature, light intensity, humidity or the like. This has the advantage that the time point of activation can be precisely controlled.

It is conceivable to provide one or more activation mechanisms. In a case where several activation mechanisms are provided, redundant activation possibilities are created. This ensures, for example, that activation is always possible.

It is further possible to provide that the nanoparticle or nanoparticles comprise a metallic material and have a surface coating, in particular a metallic surface coating and/or surface functionalization. In particular, it is possible that the nanoparticles may have electrical conductivity and/or magnetic properties.

The metallic surface coating may comprise any metal and/or metal alloy, in particular gold, silver, copper and/or bronze.

In particular, it is thus possible to obtain magnetic conductive nanoparticles (coated with conductive metal).

A metal surface of the nanoparticles may be functionalized with terminal reactive groups, in particular with polymers having at least one thiol group, such as 11-mercaptoundecanoic acid or the like, or several thiol groups, such as dithiols, in particular 1,2-ethanedithiol, 1,3-propanedithiol, 1,4-butanedithiol, 1,5-pentanedithiol, benzene-1,4-dithiol, 2,2′-ethylenedioxydiethanethiol, 1,6-hexanedithiol, tetra(ethylene glycol) dithiol, 1,8-octanedithiol, 1,9-nonanedithiol, 1,11-undecanedithiol, hexa(ethylene glycol) dithiol, 1,16-hexadecanedithiol or the like.

Furthermore, it is conceivable that the nanoparticles are, for example, round, oval, angular, rod-shaped, diamond-shaped, spherical, egg-shaped, cuboidal, cylindrical, conical, or star-shaped, or take any other common or uncommon shape.

Furthermore, it is possible that the surface coating and/or surface functionalization is formed at least partially, in particular completely, by terminal functional groups and/or linkers that selectively bind to metallic surfaces and/or SAM surfaces and/or stabilizers.

In general, it is possible that the stabilization of the nanoparticles is achieved by means of steric stabilization, electrostatic and/or electrochemical stabilization and/or further methods of stabilization.

In particular, it may be provided that the stabilizer is polyethylene glycol (PEG) and/or polyvinyl alcohol (PVA) and/or citrate, and/or organic ligands, or the like.

Further, it is possible that the surface coating is an electrically conductive surface coating, such as electrically conductive polymers.

Moreover, it is conceivable that the nanoparticles are stabilized by a matrix, in particular an environmental matrix.

It may be further provided that the matrix consists of at least one polymer, adhesive or other non-conductive material.

Moreover, it is conceivable that the nanoparticles each comprise at least one shell and at least one core. Conceivable are, for example, so-called core-shell or core-shell-shell nanoparticles.

Moreover, it is conceivable that the core contains the environmental matrix.

It is further conceivable that the nanoparticles are contained within a particle, the particle comprising at least one core and at least one shell, the or at least one core containing the at least one nanoparticle.

Conceivably, the core consists of at least one magnetic metal, in particular iron, nickel, cobalt, gadolinium, terbium, dysprosium, holmium and/or erbium.

Conceivably, the nanoparticles are magnetic nanoparticles and/or are not provided with functional groups.

Conceivably, the surface coating is formed with terminal functional groups and/or linkers that selectively bind to metallic surfaces and/or SAM surfaces and/or stabilizers and is formed in polar solvent.

It is further conceivable that at least a portion of the nanoparticles is arranged in a first capsule and a second portion of substance is provided which is also arranged in at least one capsule, wherein the capsules can each be activated.

The nanoparticles may have a substantially identical size and/or the second portions of substance may have a substantially identical size. Size may mean in particular the spatial extent, but also the mass or the volume occupied. Conceivably, the nanoparticles and the second portions of substance each have an identical size or quantity.

In particular, however, it is also conceivable that the nanoparticles and the second portions of substance have a different size.

It is conceivable, for example, that a nanoparticle is in a first capsule, and an adhesive, in particular an epoxy resin or a PU adhesive or an acrylate adhesive is in a second capsule. In particular, the formation may be provided as a double microcapsule. Activation may cause the release of the nanoparticles from the first capsule and the epoxy resin in the second capsule. This enables the formation of a conductive adhesive point. Activation may be performed as described above. In particular, this may enable precisely controlled (in time and space) electrical conductivity of a substrate.

Any form of one-component adhesive and/or resin in the sense of an adhesive is conceivable.

Any form of multi-component adhesive is also conceivable, in particular also resin and hardener. In a multi-component adhesive, the individual components may be present in different capsules and/or capsule populations and/or capsule types. 2-component adhesives are also conceivable (then, for example, one capsule for the particles, one capsule for the first adhesive component and a second capsule for the second adhesive component).

It is conceivable that the capsules (or portions of substance) can be activated and emptied at the same time.

It is conceivable that the capsules can be activated and emptied one after the other.

The choice of size also determines the respective (local) volume and/or the respective local concentration of the respective substance.

The multi-component system may have a network structure with interspaces, wherein the network structure is formed by portions of substance of the first substance, wherein an environmental medium and optionally, at least in parts, at least one portion of substance of a second substance is arranged in each of the interspaces.

The capsules are formed or functionalized with linkers and with functional groups. The linkers are intended to crosslink the capsules with one another. It may be provided that the functional groups are further provided with a protecting group. The distance between the capsules may be determined by the length of the linkers. The length of the linkers should be chosen such that the radius of the contents of the released liquid of the capsules slightly overlaps with the contents of the adjacent capsules to ensure crosslinking. For a higher viscosity environmental medium, the length of the linkers would be smaller than for a lower viscosity medium such as a paste or liquid.

In general, intra-crosslinking of capsules is possible. Here, capsules of a capsule population are cross-linked with each other.

In general, it is possible to crosslink capsules with the same content via intra-crosslinking.

In general, interlinking of capsules is possible as an alternative or in addition. Here, capsules from at least two different capsule populations are cross-linked.

In general, it is possible that capsules with different contents are networked via interlinking.

It is also possible that a selected release profile is achieved via the capsules of a multi-component capsule system, for example a two-component capsule system. For example, a gradual and/or delayed release of substances of all kinds is conceivable.

It is also conceivable that two capsule populations of a two-component capsule system are bound together on a carrier material in a batch process with the same content but with different activation mechanisms by intra-crosslinking. This may allow a longer lasting release compared to a single component capsule system.

It is generally possible to prepare capsules by physical methods, chemical methods, physiochemical methods, and/or the like.

It is generally possible to produce the capsules by solvent evaporation, thermogelling, gelation, interfacial polycondensation, polymerization, spray drying, fluidized bed, droplet freezing, extrusion, supercritical fluid, coacervation, air suspension, pan coating, co-extrusion, solvent extraction, molecular incorporation, spray crystallization, phase separation, emulsion, in situ polymerization, insolubility, interfacial deposition, emulsification with a nanomole sieve, ionotropic gelation method, coacervation phase separation, matrix polymerization, interfacial crosslinking, congealing method, centrifugation extrusion, and/or one or more other methods.

It is generally possible that the shell of the capsules comprises at least one polymer, wax resin, protein, polysaccharide, gum arabic, maltodextrin, inulin, metal, ceramic, acrylate, microgel, phase change material and/or one or more other substances.

It is generally possible that the shell of the capsules is non-porous or not entirely porous. It is generally possible that the shell of the capsules is almost completely impermeable or completely impermeable.

It is generally possible for the core of the capsules to be solid, liquid and/or gaseous.

It is generally possible for the capsules to be formed from linear polymers, polymers with multivalence, star-shaped polyethylene glycols, self-assembled monolayer (SAM), carbon nanotubes, ring-shaped polymers, DNA, dendrimers, ladder polymers, and/or the like.

Disulfites, phosphoric acids, silanes, thiols, and polyelectrolytes may be used as SAM surfaces. In particular, acetylcysteine, dimercaptosuccinic acid, dimercaptopropanesulfonic acid, ethanethiol (ethyl mercaptan), dithiothreitol (DTT), dithioerythritol (DTE), captopril, coenzyme, A, cysteine, penicillamine, 1-propanethiol, 2-propanethiol, glutathione, homocysteine, mesna, mercaptoundecanoic acid, mercaptoundecanol, methanthiol (methyl mercaptan) and/or thiophenol.

Further, the present invention relates to a method of making a multi-component conductive system having at least one first substance and having at least one substrate, wherein the first substance is present in one or more portions of substance, comprising the steps of:
the at least one or more first portions of substance are formed with at least one first functional group and provided with a first linker, and/or the substrate is formed with at least one second functional group and provided with a second linker.
   said first functional group reacts via a predefined interaction with said second functional group and/or said substrate to produce a conductive connection, and/or wherein said second functional group reacts via a predefined interaction with said first functional group and/or said first substance to produce a conductive connection.

In particular, it is conceivable that the method is carried out such that an electrically conductive multi-component system is provided with at least one first substance and with at least one second substance, wherein the first substance is present in several portions of substance, comprising the following steps:
the first portions of substance are formed with at least a first functional group and provided with a first linker,
the second substance is formed with at least a second functional group and provided with a second linker,
the first functional group is reacted via a predefined interaction with the second functional group so as to bind them together, and
the distance of the functional groups to the respective portions of substance is determined by the respective linker.

It can be provided in particular that the first portions of substance are formed with at least one third functional group and are provided with a third linker, the third functional group each having at least one protective group, so that only correspondingly functionalized portions of substance of the first substance can bind to the portions of substance of the first substance, and the method further comprising at least the step that the protective groups initially present are only removed when the first portions of substance are to be linked to one another by means of the third functional groups. This prevents the portions of substance, in particular capsules, of the first substance (i.e. the first portions of substance) from already and preferably combining with further portions of substance of the first substance. The protective groups can be removed after being introduced into gas, low viscosity, liquid, high viscosity, or solid phase, whereby intra-crosslinking takes place.

Additionally, it may be provided that the multi-component system is a multi-component system according to any one of claims 1 to 12.

Possible protecting groups include acetyl, benzoyl, benzyl, ß-methoxyethoxymethyl ether, methoxytriyl, 4-methoxyphenyl)diphenylmethyl, dimethoxytrityl, bis-(4-methoxyphenyl)phenylmethyl, methoxymethyl ether, p-methoxybenzyl ether, methyl thiomethyl ether, pivaloyl, tetrahydrofuryl, tetrahydropyranyl, trityl, triphenyl methyl, silylether, tert-butyldimethylsilyl, tr-iso-propylsilyloxymethyl, triisopropylsilyl, methyl ether, ethoxyethyl ether.p-methoxybenzylcarbonyl, tert-butyloxycarbonyl, 9-fluorenylmethyloxycarbonyl, carbamates, p-methoxybenzyl, 3,4-dimethoxybenzyl, p-methoxyphenyl, one or more tosyl or nosyl groups, methyl esters, benzyl esters, tert-butyl esters, 2, 6-di-substituted phenol esters (e. g.e.g. 2,6-dimethylphenol, 2,6-diisopropylphenol, 2,6-di-tert-butylphenol), silyl esters, orthoesters, oxazoline, and/or the like.

Possible materials for coating the capsules include albumin, gelatin, collagen, agarose, chitosan, starch, carrageenan, polystarch, polydextran, lactides, glycolides and copolymers, polyalkylcyanoacrylate, polyanhydride, polyethyl methacrylate, acrolein, glycidyl methacrylate, epoxy polymers, gum arabic, polyviyl alcohol, methyl cellulose, carboxymethyl cellulose, hydroxyethyl cellulose, arabinogalactan, polyacrylic acid, ethyl cellulose, polyethylene polymethacrylate, polyamide (nylon), polyethylene vinyl acetate, cellulose nitrate, silicones, poly(lactide-co-glycolide), paraffin, camauba, spermaceti, beeswax, stearic acid, stearyl alcohols, glyceryl stearate, shellac, cellulose acetate phthalate, zein, hydrogels or the like.

Possible functional groups include alkanes, cycloalkanes, alkenes, alkynes, phenyl substituents, benzyl substituents, vinyl, allyl, carbenes, alkyl halides, phenol, ethers, epoxides, ethers, peroxides, ozonides, aldehydes, hydrates, imines, oximes, hydrazones, semicarbazones, hemiacetals, hemiketals, lactols, acetal/ketal, aminals, carboxylic acid, carboxylic acid esters, lactones, orthoesters, anhydrides, imides, carboxylic acid halides, carboxylic acid derivatives, amides, lactams, peroxyacids, nitriles, carbamates, ureas, guanidines, carbodiimides, amines, aniline, hydroxylamines, hydrazines, hydrazones, azo compounds, nitro compounds, thiols, mercaptans, sulfides, phosphines, P-ylene, P-ylides, biotin, streptavidin, metallocenes, or the like.

Possible release mechanisms include diffusion, dissolution, degradation control, erosion, pressure, induction, ultrasound, or the like.

It is conceivable that there is a combined release mechanism.

Possible fields of application of the process or system according to the invention include biotechnology, electrical engineering, mechanical engineering, medical engineering and/or microtechnology or the like.

In principle, other fields of application are also possible.

Further details and advantages of the invention will now be explained with reference to an example embodiment shown in more detail in the drawings.

The following is shown:

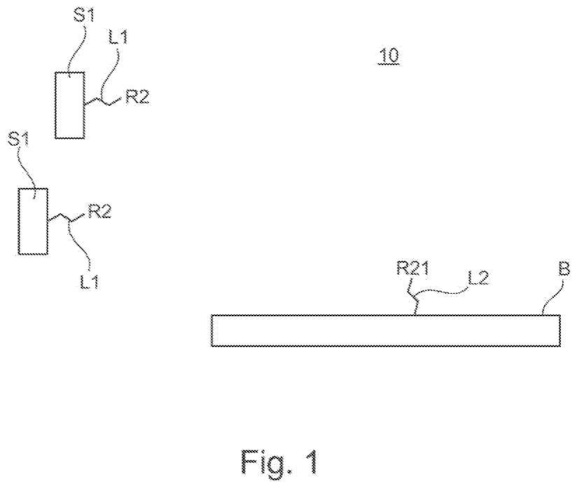

FIG. 1 an embodiment of a multi-component system according to the invention with a first substance and a substrate;

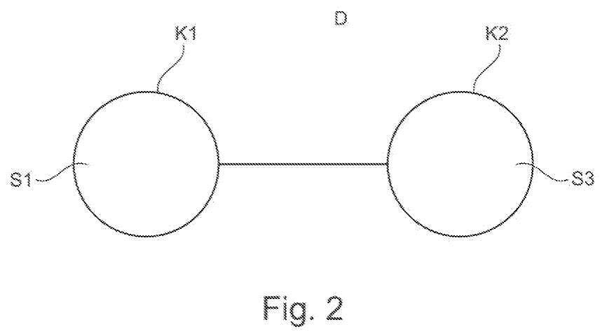

FIG. 2 a further embodiment of a multi-component system according to the invention with a first substance and a second substance,

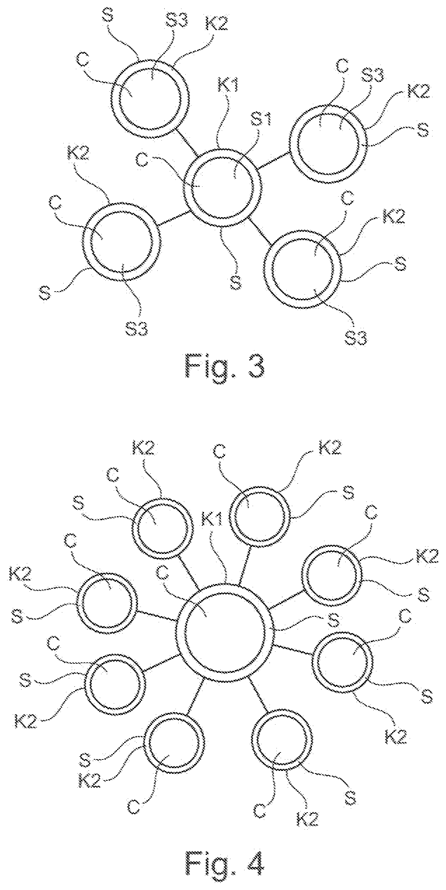

FIG. 3 a further embodiment of a multi-component system according to the invention as shown in FIG. 1;

FIG. 4 a further embodiment of a multi-component system according to the invention as shown in FIG. 1 or FIG. 3;

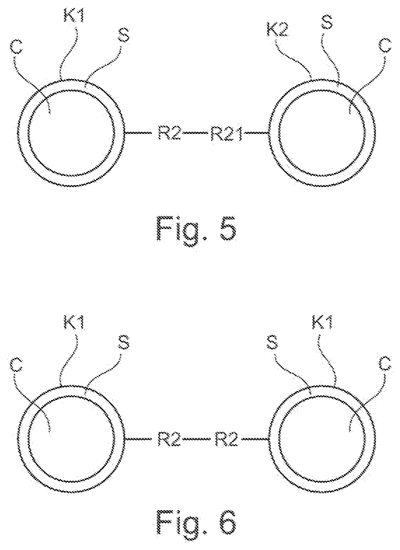

FIG. 5 an embodiment of an interlinking of two different portions of substance according to the invention;

FIG. 6 an embodiment of an intra-crosslinking of two equal portions of two different portions of substance according to the invention;

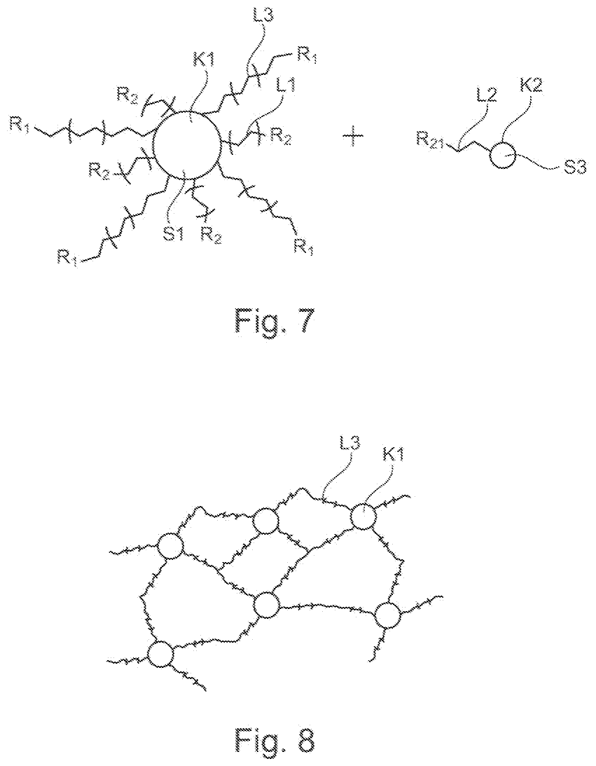

FIG. 7 a further embodiment of a multi-component system 10, 110 according to the invention (according to FIG. 1 and FIG. 2);

FIG. 8 an embodiment of an interlinked capsule system according to the invention;

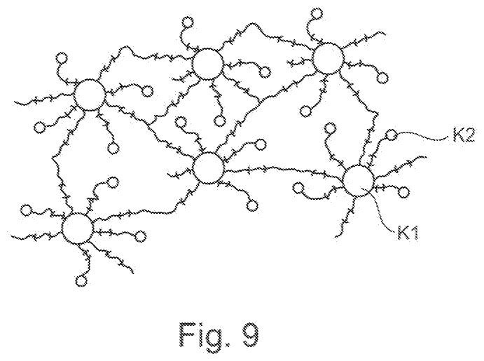

FIG. 9 an embodiment of an inter- and intra-crosslinked multi-component system according to the invention as shown in FIG. 7;

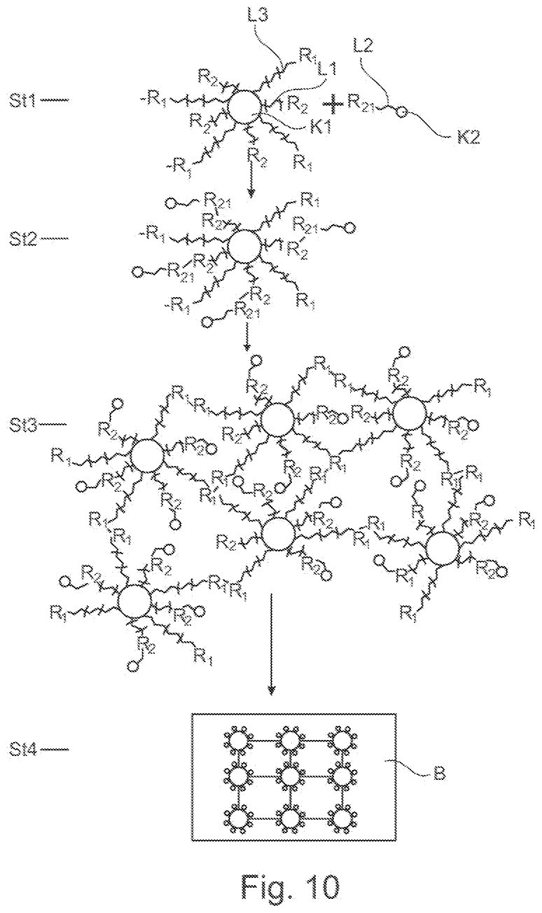

FIG. 10 A flowchart of the workflow of manufacturing an electrically conductive multi-component system according to the present invention;

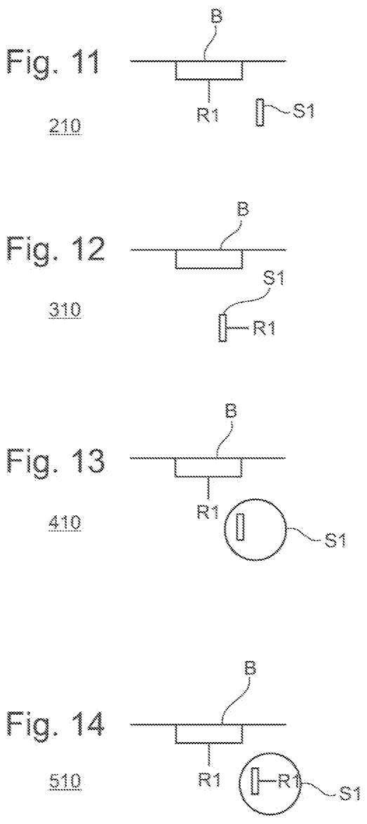

FIG. 11 a schematic representation of a further embodiment of a multi-component system according to the invention;

FIG. 12 a schematic representation of a further embodiment of a multi-component system according to the invention;

FIG. 13 a schematic representation of a further embodiment of a multi-component system according to the invention;

FIG. 14 a schematic representation of a further embodiment of a multi-component system according to the invention;

FIG. 15 a schematic representation of a further embodiment of a multi-component system according to the invention;

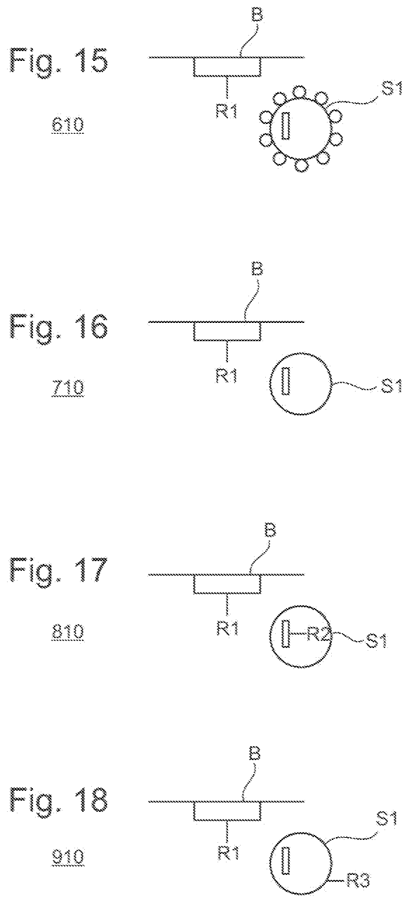

FIG. 16 schematic representation of a further embodiment of a multi-component system according to the invention;

FIG. 17 a schematic representation of a further embodiment of a multi-component system according to the invention;

FIG. 18 a schematic representation of a further embodiment of a multi-component system according to the invention;

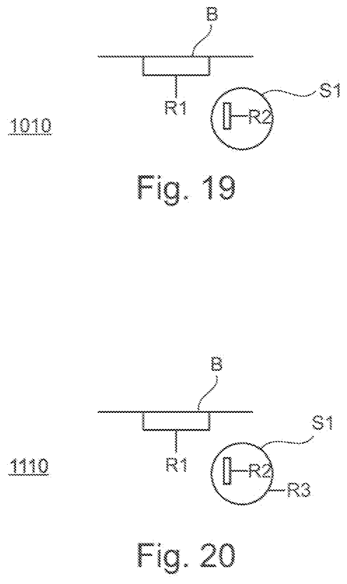

FIG. 19 a schematic representation of a further embodiment of a multi-component system according to the invention;

FIG. 20 a schematic representation of a further embodiment of a multi-component system according to the invention;

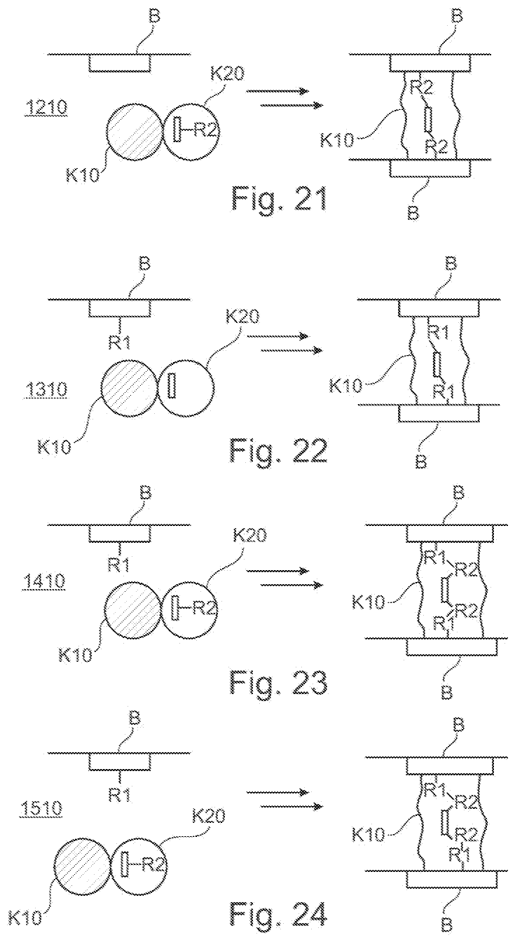

FIG. 21 a schematic representation of a further embodiment of a multi-component system according to the invention;

FIG. 22 a schematic representation of a further embodiment of a multi-component system according to the invention;

FIG. 23 a schematic representation of a further embodiment of a multi-component system according to the invention;

FIG. 24 a schematic representation of a further embodiment of a multi-component system according to the invention;

FIG. 25 a schematic representation of a further embodiment of a multi-component system according to the invention;

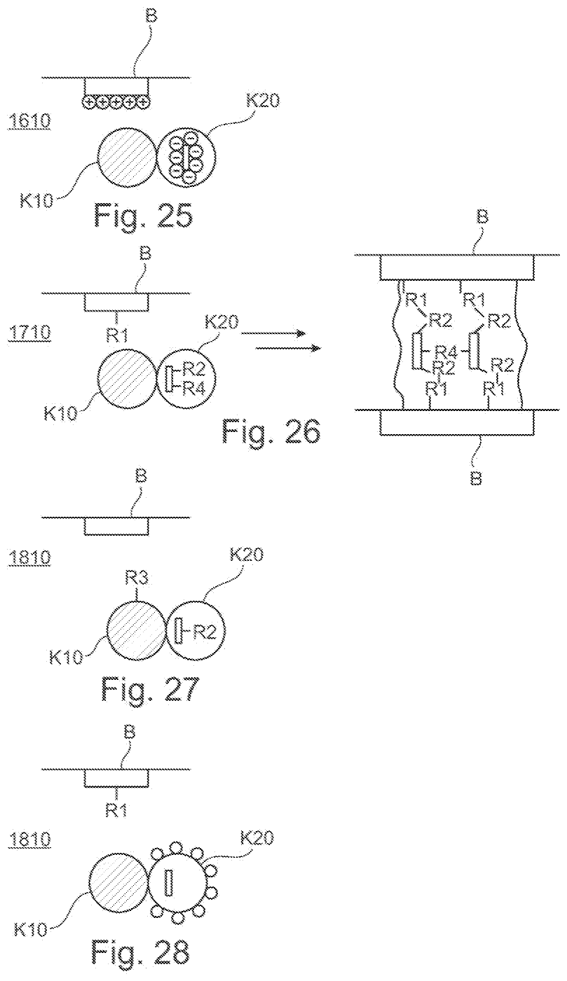

FIG. 26 a schematic representation of a further embodiment of a multi-component system according to the invention;

FIG. 27 a schematic representation of a further embodiment of a multi-component system according to the invention;

FIG. 28 a schematic representation of a further embodiment of a multi-component system according to the invention;

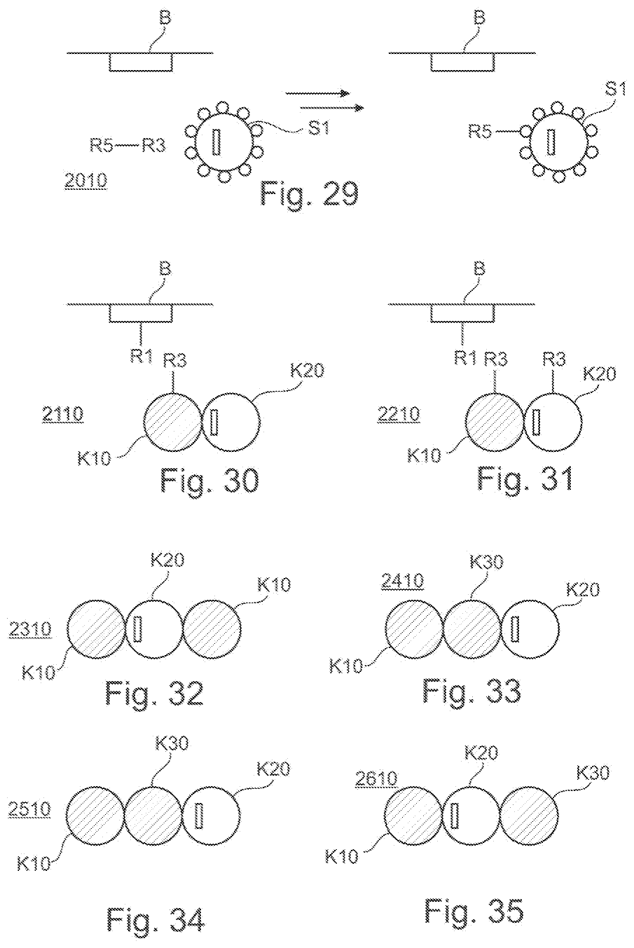

FIG. 29 a schematic representation of a further embodiment of a multi-component system according to the invention;

FIG. 30 a schematic representation of a further embodiment of a multi-component system according to the invention;

FIG. 31 a schematic representation of a further embodiment of a multi-component system according to the invention;

FIG. 32 a schematic representation of a further embodiment of a multi-component system according to the invention;

FIG. 33 a schematic representation of a further embodiment of a multi-component system according to the invention;

FIG. 34 a schematic representation of a further embodiment of a multi-component system according to the invention; and

FIG. 35 a schematic representation of a further embodiment of a multi-component system according to the invention.

FIG. 1 shows an embodiment of an electrically conductive multi-component system 10 according to the invention with a first substance S1 and with a substrate B. In principle, any type of conductivity (electrical conductivity, heat, signals, etc.) can be achieved in this way.

In this embodiment, the electrically conductive multi-component system 10 includes a first substance S1.

The first substance S1 is present in several portions of substance.

The first portions of the substance are formed with a functional group R (R2).

Alternatively, first portions of substance may be formed with more than one functional group R.

The first portions of substance are provided with a first linker L (L1).

Alternatively, the electrically conductive multi-component system may include more than one first substance S1.

In this embodiment, the electrically conductive multi-component system 10 includes a substrate B.

Alternatively, the electrically conductive multi-component system 10 may include more than one substrate B.

In this embodiment, the substrate B is formed with at least one second functional group R (R21).

In this embodiment, the substrate B is provided with a second linker L (L2).

Not shown in FIG. 1 is that the first functional group R (R2) reacts via a predefined interaction with the second functional group R (R21), bonding them together.

Not shown in FIG. 1 is that the distance of the functional groups R (R2, R21) from the portion of substance and the substrate B is determined by the respective linker L (1, L2), wherein a portion of substance of the first substance S1 is present as nanoparticles or in nanoparticles and is at least partially electrically conductive.

Not shown in FIG. 1 is that the nanoparticle is a ferromagnetic nanoparticle and is coated with a conductive metal surface coating.

In general, however, other magnetic nanoparticles or conductive surfaces are also conceivable.

Not shown in FIG. 1 is that the substrate B may be a surface or is a surface.

Not shown in FIG. 1 is that the surface may be a wafer or a printed circuit board or the like.

Not shown in FIG. 1 is that the surface may be a conductive substrate B.

Not shown in FIG. 1 is that, alternatively, the surface may be provided with conductor paths.

Further not shown in FIG. 1 is that the first linker L (L1) may be longer than the second linker L (L2) or vice versa.

Further not shown in FIG. 1 is that the functional groups R (R2, R21) may be homogeneous or heterogeneous.

Further not shown in FIG. 1 is that a portion of substance of the first substance S1 may be arranged in a capsule K, in particular a nanocapsule and/or microcapsule.

Not explicitly shown in FIG. 1 is that the capsules K1 of the first substance S1 may have an identical size.

Further not shown in FIG. 1 is that at least parts of the multi-component system 10 can be activated and that the activation of the multi-component system 10 is performed by at least one of a change in pressure, pH, UV radiation, osmosis, temperature, light intensity, humidity, ultrasound or the like.

In other words, it is not shown in FIG. 1 that by activating one or more parts of the multi-component system, an electrically conductive system can be enabled.

Further not shown in FIG. 1 is that the nanoparticle or nanoparticles comprise a metallic substance and have a surface coating, in particular a metallic surface coating and/or surface functionalization.

Further not shown in FIG. 1 is that the surface coating and/or surface functionalization is formed at least partially, in particular completely, by terminal functional groups R and/or linkers L that selectively bind to metallic surfaces and/or SAM surfaces and/or stabilizers.

It is not shown in FIG. 1 that it is generally possible for the nanoparticles to be stabilized by a matrix, particularly an environmental matrix.

Further it is not shown in FIG. 1 that the nanoparticles each comprise at least one shell S and at least one core C.

Further not shown in FIG. 1 is that the nanoparticles are incorporated into a particle, the particle comprising at least one core C and at least one shell S, the one or at least one core C containing the at least one nanoparticle.

Further not shown in FIG. 1 is that at least a portion of the nanoparticles is arranged in a first capsule K1 and a second portion of substance S3 is provided which is also arranged in at least one capsule K, wherein the capsules K can each be activated.

Not shown in FIG. 1 is a corresponding method for producing an electrically conductive multi-component system having at least one first substance S1 and having at least one substrate B, wherein the first substance S1 is present in a plurality of portions of substance, comprising the following steps:
the first portions of substance S1 are formed with at least one first functional group R (R2) and provided with a first linker L (L1),
the substrate B is formed with at least a second functional group R (R21) and provided with a second linker L (L2),
the first functional group R (R2) reacts via a predefined interaction with the second functional group R (R21) so that they are bonded together, and the distance of the functional groups R (R2, R21) to the respective portion of substance is determined by the respective linker L (L1, L2).

Further not shown in FIG. 1 is that the first portions of substance are formed with at least one third functional group R (R1) and are provided with a third linker L (L3), wherein the third functional group R (R1) may each have at least one protective group so that only correspondingly functionalized portions of substance of the first substance S1 can bind to the portions of substance of the first substance S1, and wherein the method further comprises at least the step that the protective groups are initially present and are only removed when the first portions of substance are to be connected to each other by means of the third functional groups R (R1).

It is further not shown in FIG. 1 that the multi-component system is a multi-component system according to any one of claims 1 to 12.

Not shown in FIG. 1 is that the functional groups R1, R2 and R21 are each replaceable by a different functional group R.

In general, all embodiments of functional groups R forming bonds with each other are conceivable.

FIG. 2 shows another embodiment of a multi-component system 10, 110 according to the invention with a first substance S1 and with a second substance S3.

The multi-component system 110 includes all of the structural and functional features of the multi-component system 10 shown in FIG. 1.

In this embodiment, at least a portion of the nanoparticles is arranged in a first capsule K1.

In addition, in this embodiment, a second portion of substance S3 is provided which is also arranged in at least one capsule K2, wherein the capsules K1, K2 can each be activated.

In this embodiment, the capsules K1, K2 can be activated by a change in pressure.

Alternatively, activation of the capsules K1 and/or K2 may be accomplished by a change in pH, UV radiation, osmosis, temperature, light intensity, ultrasound, induction, humidity, or the like.

The functional groups of the capsules K1 and K2 are bound together.

Not shown in FIG. 2 is that the second substance and/or the second portion of substance S3 is an adhesive, in particular an epoxy resin, polyurethane, acrylate, silicone, combinations thereof, or the like.

In other words, the embodiment provides for a dual-microcapsule D.

In general, any other form of multiple microcapsule is possible using the same principle.

It is not shown in FIG. 2 that activation causes the release of the nanoparticles from the first capsule K1 and the adhesive, such as epoxy resin from the second capsule K2.

Not shown in FIG. 2 is that this enables the formation of a conductive adhesive dot.

Not shown in FIG. 2 is that multiple microcapsules, e.g. dual-microcapsules, are produced via microfluidics.

It is not shown in FIG. 2 that free functional groups R are blocked by a blocking substance.

Not shown in FIG. 2 is that free functional groups R are blocked by ethanolamine.

FIG. 3 shows a further embodiment of a multi-component system 10, 110 according to the invention as shown in FIG. 1.

In this embodiment, at least a portion of the nanoparticles is arranged in a first capsule K1.

In this embodiment, a second portion of substance S3 is provided, which is also arranged in at least one capsule K2, wherein the capsules K1, K2 can each be activated.

The first and second capsules K1, K2 are connected to each other.

Capsules K1, K2 each comprise a shell S and a core C.

In other words, as in the embodiment of FIG. 2, the multi-component system according to this embodiment comprises two different substances S1, S3 and/or capsule populations K1, K2.

Not shown in FIG. 3 is that the first capsule K1 and/or the second capsule may be bound to a substrate B (FIG. 1) or may bind to a substrate B (via functional groups R).

In this embodiment, the first portions of substance and the second portions of substance are different.

In other words, in this embodiment, the capsules K1 of the first capsule population are different from the capsules K2 of the second capsule population.

In this embodiment, the first portions of substance are connected or connectable to a greater number of portions of substance than the second portions of substance.

In other words, in this embodiment, the capsules K1 are connected or connectable to a greater number of capsules K than the capsules K2.

Alternatively, it is possible that the second portions of substance are connected or connectable to a greater number of portions of substance than the first portions of substance.

Alternatively, it is possible that the second capsules K2 are connected or connectable to an equal number of capsules K as the first capsules K1.

In other words, it is possible that the capsules K2 are connected or connectable to a greater number of capsules K than the capsules K1.

FIG. 4 shows a further embodiment of a multi-component system according to the invention as shown in FIG. 1 or FIG. 3.

In this embodiment, the first portions of substance and the second portions of substance are substantially different in size.

In this embodiment, the first capsules K1 are substantially larger in size than the second capsules K2.

In general, a capsule K1 for a first substance S1 may have a different size than a capsule K2 for a second substance S3, in particular wherein the capsule K1 for the first substance S1 is larger than the capsule K2 for the second substance S3.

Alternatively, it is possible for the second portions of substance to have a substantially larger size than the first portions of substance.

Alternatively, it is possible for the first portions of substance and the second portions of substance to be of substantially identical size.

Not shown is that the first portions of substance may have a substantially identical size and/or that the second portions of substance may have a substantially identical size.

Capsules K1, K2 each comprise a shell S and a core C.

FIG. 6 shows an embodiment of an interlinking of two different portions of substance according to the invention.

In this embodiment, a capsule K1 and a capsule K2 are interlinked.

In this embodiment, a capsule K1 and a capsule K2 are interlinked via functional groups R2 and R21.

Not shown in FIG. 5 is that the functional groups R2 and R21 can each be replaced by a different functional group R.

In general, all embodiments of functional groups R forming bonds with each other are conceivable.

Not shown in FIG. 5 is that an inter-crosslinking of the first capsule K1 with a substrate B (instead of the second capsule K2) can take place (cf. FIG. 1).

Capsules K1, K2 each comprise a shell S and a core C.

Alternatively, the capsules K1, K2 may not comprise a shell S and/or a core.

FIG. 6 shows an embodiment of an intra-crosslinking of two equal portions of substance according to the invention.

In this embodiment example, two capsules K1 are intra-cross-linked.

In this embodiment, the two capsules K1 are intra-cross-linked via the functional groups R (R2).

Capsules K1, K2 each comprise a shell S and a core C.

Alternatively, the capsules K1, K2 may not comprise a shell S and/or a core.

FIG. 7 shows a further embodiment of a multi-component system 10, 110 according to the invention (according to FIG. 1 and FIG. 2).

In this embodiment, the multi-component system is a microcapsule system.

In particular, two different capsule populations K1 and K2 are shown, wherein a first substance is in the first capsule K1 and a second substance is in the second capsule K2.

The capsules K1 and K2 shown are exemplary of a plurality of capsules K1 and K2, e.g. to be referred to as capsule populations.

In this embodiment, the first substance S1 in the capsule K1 is a nanoparticle.

In other words, the one first portion of substance is present as nanoparticles.

In this embodiment, the second substance S3 in the second capsule K2 is a second component.

In this embodiment, the second substance S3 is an adhesive.

In this embodiment, the second substance S3 is an epoxy resin.

In general, all forms of adhesive are possible.

In other words, the first substance S1 and the second substance S3 are components of a multi-component system.

In other words, the first substance S1 and the second substance S3 are components of an electrically conductive multi-component system 10,110.

It is generally possible that the two different capsule populations K1 and K2 were produced in separate batch reactors.

The K1 and K2 capsules of the two capsule populations are functionalized.

The first capsules K1 were formed with two different linkers L1 and L3 of different length and with different functional groups R1 and R2 on the surface (surface functionalization).

In other words, the functional groups R are formed heterogeneously.

In an alternative embodiment, it is possible that the functional groups R are homogeneously formed.

The second capsules K2 were formed with the linker L2 and with the functional group R21.

The functional group R21 of the second capsule K2 reacts covalently with the functional group R2 of the first capsule K1.

Not shown in FIG. 7 is that the functional groups R1, R2 and R21 are each replaceable by a different functional group R.

In general, all embodiments of functional groups R forming bonds with each other are conceivable.

In this embodiment, it is possible that the first capsules K1 are connected or connectable to a greater number of capsules K than the second capsules K2.

In an alternative embodiment, it is possible that the second capsules K2 are connected or connectable to a larger number of capsules K than the first capsules K1.

The linker L3 is to crosslink the first capsules K1 with each other (intra-crosslinking).

Via the linker L1 and the linker L2, the capsules K2 are covalently bound to the first capsule K1 (interlinking).

By activating both capsules K1 and K2, the contents of the capsules K1 and K2 can be released.

It is generally possible to determine the number of second capsules K2 that bind to the first capsules K1 via the density of the surface functionalization or number of functional groups R2 of the first capsule K1.

In general, two substances S1, S3 may be separately encapsulated in the capsules K1 and K2 and bound in a specific ratio, inter alia, by a covalent bond (e.g. click chemistry), by weak interaction, biochemically (e.g. biotin-streptavidin), covalently or by other means.

It is generally possible for more than two different capsules Kn to encapsulate more than two different substances, e.g. reactive substances.

It is generally possible that the different capsules Kn are functionalized with more than two linkers Ln and with different functional groups Rn.

It is generally possible for a linker L to be any form of link between a capsule and a functional group.

It is generally possible that in heterogeneous functionalization, a functional group R can be used to bind to surfaces, conductor paths, fibers, or textiles.

Activation of the multi-component system may be accomplished by at least one of a change in pressure, pH, UV radiation, osmosis, temperature, light intensity, humidity, ultrasound, induction, or the like.

In general, a multi-component capsule system could be used in any medium.

Not shown in FIG. 7 is that the first capsule K1 and/or the second capsule may be bonded or bind to the substrate B (FIG. 1).

Not shown in FIG. 7 is that a conductive structure, in particular a conductive substrate B, can thus be provided.

FIG. 8 shows an embodiment of an intra-cross-linked capsule system according to the invention.

In this embodiment, the intra-cross-linked capsule system according to the invention is an intra-cross-linked microcapsule system.

Shown is a single component system.

Shown is a capsule population K1.

The capsules K1 are filled with a substance.

In other words, the capsules K1 can be seen as portions of substance of a first substance.

The portions of substance are present as nanoparticles.

In this embodiment, the nanoparticles are present as magnetic nanoparticles with an electrically conductive surface coating.

In this embodiment, the nanoparticles are present as ferromagnetic nanoparticles with an electrically conductive silver surface coating.

Alternatively, other conductive surface coatings and/or magnetic nanoparticles are conceivable.

The capsules K1 were functionalized.

Capsules K1 were formed with linkers L3.

Not shown is that capsules K1 are functionalized with functional groups R1 (at linker L3).

The linkers L3 crosslink the capsules K1 with each other (intra-cross-linking).

The distance between the capsules K1 can be determined by the length of the linker L3.

Depending on the density of the surface functionalization R1, the degree of intra-cross-linking of the capsules K1 can be determined.

The length of the linker L3 has to be chosen in such a way that the nanoparticles have the desired distance to each other.

FIG. 9 shows an embodiment of an inter- and intra-cross-linked multi-component system according to the invention as shown in FIG. 7.

The first capsules K1 and the second capsules K2 are filled with different substances.

In this embodiment, the capsules K1 have a substantially identical size.

In this embodiment, the capsules K2 have a substantially identical size.

In this embodiment, the capsules K1 and the capsules K2 have a different size.

In an alternative embodiment, it is possible that the capsules K1 and the capsules K2 have a substantially identical size.

The basic system corresponds to the illustration in FIG. 8.

In this embodiment, the first substance S1 in the one capsule K1 is a nanoparticle.

In other words, the one first portion of substance is present as nanoparticles.

In this embodiment, the second substance S3 in the second capsule K2 is a second component.

In this embodiment, the second substance S3 is an adhesive.

In this embodiment, the second substance S3 is an epoxy resin.

In general, all forms of adhesive are possible.

In other words, the first substance S1 and the second substance S3 are components of a multi-component system.

In other words, the first substance S1 and the second substance S3 are components of an electrically conductive multi-component system 10,110.

Moreover, the first capsules K1 are heterogeneously functionalized with a linker L1.

A second capsule population K2 binds to the linker L1, cf. FIG. 2, 3, 4 or 7.

In other words, the multi-component system has a network structure with interstices, wherein the network structure is formed by the first capsules K1, and wherein at least one capsule K2 is arranged in each of the interstices, at least in sections.

It is generally possible that the capsules K1 and K2 with different contents, are introduced into a gas phase.

Substrates B and/or surfaces could also be coated with this dispersion.

It is generally possible for the capsules K1 and K2 with different contents to be introduced into a paste-like medium. The paste is inactive and can be processed well until the capsules are activated and react with each other.

The advantage of the ideal composition of the capsule systems can also be used in liquid systems. Since both capsules K1 and K2 of the two-component capsule system are in close proximity, it is very likely that the capsules K1 and K2 react faster and more defined with each other than individually in dispersion.

FIG. 10 shows a flowchart of the workflow of manufacturing an electrically conductive multi-component system 10, 110 according to the invention.

FIG. 10 is substantially based on a multi-component capsule system according to FIG. 2, 3, 4 or 7.

In this embodiment, the first substance S1 in the one capsule K1 is a nanoparticle.

In other words, the one first portion of substance is present as nanoparticles.

In this embodiment, the second substance S3 in the second capsule K2 is a second component.

In this embodiment, the second substance S3 is an adhesive.

In this embodiment, the second substance S3 is an epoxy resin.

In general, all forms of adhesive are possible.

In other words, the first substance S1 and the second substance S3 are components of a multi-component system.

In other words, the first substance S1 and the second substance S3 are components of an electrically conductive multi-component system 10,110.

Overall, the preparation of an electrically conductive multi-component system according to the invention is divided into four steps St1-St4.

In a first step St1, the first capsules K1 and the second capsules K2 are functionalized, cf. FIG. 7.

In the present multi-component system, the first capsules K1 are heterogeneously functionalized with two linkers L1 and L3 with functional groups R1 and R2.

In a separate batch, the second population of capsules K2 is functionalized with linker L2 and functional group R21.

The functional group R21 is to be chosen such that it reacts (covalently) with the functional group R2 of the first capsule K1 in the later reaction step.

In a second step St2, the functionalized second capsules K2 are added to the functionalized first capsules K1.

The functional groups R2 and R21 bind (covalently) to each other.

It is generally possible that a third or any number of further capsule populations K3-Kn are also added to a first capsule population K1 and/or a second capsule population K2.

Each additional capsule population K3-Kn may in turn be functionalized with at least one functional group.

In a third step St3, a predetermined (intra)-crosslinking reaction occurs.

In a fourth step St4, the cross-linked multi-component capsule populations are applied to a substrate B.

Substrate B is also provided with a linker L and a functional group R.

Not shown in FIG. 10 is that the capsules K1 and/or K2 can bind to the functional groups R of the substrate B through linkers L with functional groups R.

It is not shown that in step St1, in order to prevent the first capsules K1 from prematurely crosslinking with each other during functionalization, a protecting group may still be formed on the functional group R1 of the linker L3.

Not shown is that in step St3 the protective group is removed.

Not shown in FIG. 10 is that a conductive structure, in particular a conductive substrate B, can thus be provided.

It is generally possible for the capsules K to be nanocapsules or microcapsules.

In principle, nanoparticles may be used in any of the embodiments described above and below:

Quantum dots, metallic nanoparticles, metal salt nanoparticles, oxides, sulfides, core-shell particles, self-assembly particles, doped nanoparticles, magnetic semiconductor nanoparticles, doped nanoparticles like TiO2 doped nanoparticles with cobalt and multilayers like Fe/Si, Cu/Ni, Co/Pt etc., semiconductor nanoparticles like ZnS, CdS, ZnO.

Essentially, any conceivable form of nanoparticle can be considered.

Homogeneous functionalization of the nanoparticles can be achieved with thiol or dithiol groups.

The embodiments shown in FIGS. 11-16 relate to embodiments with a linker.

FIG. 11 shows another embodiment of a multi-component system 210 according to the invention.

Here, a functionalized substrate B is present with a substance S1, here directly present as a particle. This is an alternative embodiment with a linker.

The substrate B is functionalized with a functional group R1. The (nano)-particle binds to the functional group and thus to the substrate B.

FIG. 12 shows another embodiment of a multi-component system 310 according to the invention.

The substance S1 is a functionalized (nano)-particle with substrate B.

In this case, the (nano)-particle is functionalized with a functional group R1. The functionalized (nano)-particle binds to the substrate B.

FIG. 13 shows another embodiment of a multi-component system 410 according to the invention.

This is a functionalized substrate B with (nano)-particles in portion of substance S1, here in the form of a microcapsule.

The substrate B is functionalized with a functional group R1. The (nano)-particle is located in a portion of substance S1. By activating the portion of substance, the (nano)-particle is released and binds to the functional group of substrate B.

FIG. 14 shows another embodiment of a multi-component system 510 according to the invention.

This is a functionalized (nano)-particle in portion of substance S1 (microcapsule) with substrate B.

The (nano)-particle is functionalized with a functional group R1 and is located in a portion of substance S1. By activating the portion of substance, the (nano)-particle binds to the substrate B.

FIG. 15 shows another embodiment of a multi-component system 610 according to the invention.

This is a functionalized substrate B with a functional group R1 with (nano)-particles in portion of substance S1, which also has (metal)-particles on the surface.

The substrate B is functionalized with a functional group R1. The nanoparticle is located in a portion of substance S1. By activating the portion of substance S1, the (nano)-particle binds to the substrate B.

FIG. 16 shows another embodiment of a multi-component system 710 according to the invention.

Here, a functionalized portion of substance S1 with (nano)-particles and substrate B is present.

The portion of substance S1, in which a (nano)-particle is located, is functionalized with a functional group R1. By binding the functional groups of the portion of substance S1 to the substrate B, the portion of substance S1 can be precisely placed. The (nano)-particle binds to the substrate B by activation.

The embodiments shown in FIGS. 17-20 relate to variants with two linkers.

FIG. 17 shows another embodiment of a multi-component system 810 according to the invention.

This is a functionalized substrate B with functionalized (nano)-particle.

The substrate B is functionalized with a functional group R1. The (nano)-particle is functionalized with a functional group R2. Via an activation/reaction, the functional group R1 binds to the substrate B with the functional group R2.

FIG. 18 shows another embodiment of a multi-component system 910 according to the invention.

Here, it is a functionalized substrate B with functionalized portion of substance S1, in which at least one (nano)-particle is present.

The substrate B is functionalized with a functional group R1. The portion of substance S1 is functionalized with a functional group R3. The portion of substance S1 contains at least one (nano)-particle. The portion of substance S1 can be precisely placed via the complementary functional groups R1 and R3. Through activation/reaction, the (nano)-particle is released and binds to the substrate B.

FIG. 19 shows another embodiment of a multi-component system 1010 according to the invention.

Here, we are concerned with a functionalized substrate B with functionalized (nano)-particles, which are located in a portion of substance S1.

The substrate B is functionalized with a functional group R1. In the portion of substance S1 there is at least one functionalized (nano)-particle with a functional group R2.

FIG. 20 shows another embodiment of a multi-component system 1110 according to the invention.

Here, it is a functionalized substrate B with functionalized (nano)-particles, which are located in a portion of substance S1, which is also functionalized. The substrate B is functionalized with a functional group R1. The (nano)-particle is functionalized with a functional group R2. The portion of substance S1 is functionalized with a functional group R3. Thus, the portion of substance can be precisely positioned via the functional groups R1 and R3. Via an activation of the portion of substance S1, the (nano)-particles are released in a site-specific manner. The shell of the portion of substance S1 can stabilize the (nano)-particles.

FIG. 21 shows another embodiment of a multi-component system 1210 according to the invention, namely a system with double microcapsules with functionalization of the (nano)particles.

In this case, the capsule K10 is filled with adhesive and the capsule K20 is filled with (electrically) conductive particles (e.g. one or more rod-shaped nanoparticles).

In this embodiment, the first microcapsule contains adhesive, and the second microcapsule contains at least one (nano)particle and/or carbon nanotube.

An adhesive is encapsulated in microcapsule K10. Microcapsule K20 contains at least one (nano)-particle which is made of an (electrically) conductive material.

Thereby, the surface of the (nano)-particles may be functionalized with functional groups R, such as terminal thiol groups or other functional groups R. The shell of microcapsule K10 may be of the same material and of the same thickness as shell of microcapsule K20. Moreover, microcapsule K10 may have the same size as microcapsule K20. However, the parameters may also differ from each other in at least one or more points.

The mechanism may be a parallel opening mechanism:

The microcapsules are applied to metal areas/metal surfaces. Subsequently, a second metal surface is positioned parallel to the first metal surface. Through a defined activation mechanism, both microcapsules are opened simultaneously and the contents are released. The released nanoparticles, functionalized with terminal functional groups, such as thiol groups, bind to both surfaces of the parallel metal surfaces. The (nano)-particles form a network among each other. This can be done by aggregation and/or by binding of the functional groups, such as thiol groups, to each other (interlinking). After activation of the adhesive-filled microcapsule K10, the latter is emptied and stabilizes the (nano)-particle connection of the (electrically)-conductive compound. In addition, the adhesive connects the upper and lower surfaces with each other.

A sequential opening mechanism is also conceivable:

The microcapsules are applied to the metal areas. Thereby, the microcapsule K10 has a different opening mechanism than the microcapsule K20. Subsequently, a second metal surface is positioned parallel to the first metal surface. By means of a defined activation mechanism, such as temperature, the microcapsule with the (nano)particles is opened firstly and its contents are released. Thereby, the released nanoparticles functionalized with terminal functional groups R2, such as thiol groups, bind to both surfaces of the parallel attached metal surfaces. Among each other, the (nano)-particles form a network. This can be done by aggregation and/or by binding of the functional groups, such as thiol groups, to each other (inter- and intra-crosslinking). By a second opening mechanism, which is preferably achieved by the microcapsule K10 having a different shell material than the microcapsule K20 and/or a different size and/or thickness of the shell material than the microcapsule K10. Conceivably, a second activation mechanism could include, for example, ultrasound, pH change, induction, pressure, etc. In addition, sequential activation can be achieved by varying the first activation mechanism, e.g. by increasing the temperature. After activation of the adhesive-filled microcapsule 1, the latter is emptied and stabilizes the (nano)-particle connection of the (electrically)-conductive (nano)-particles. In addition, the adhesive bonds the upper and lower surfaces together.

FIG. 22 shows another embodiment of a multi-component system 1310 according to the invention, namely the alternative of functionalization of the (electrically) conductive surface.

An adhesive is encapsulated in the microcapsule K10. Microcapsule K20 contains (nano)-particles which are made of an (electrically) conductive material. Thereby, the (electrically) conductive surface of the conductive path is functionalized with terminal thiol groups. The (nano)-particles are not functionalized.

The mechanism may be a parallel opening mechanism:

The microcapsules are applied to the metal areas. Subsequently, a second metal surface is positioned parallel to the first metal surface. Through a defined activation mechanism, both microcapsules are opened simultaneously and the contents are released. The released nanoparticles bind to both surfaces of the parallel metal surfaces, which are functionalized with terminal thiol groups. The (nano)-particles form a network among each other. This occurs through aggregation among each other.

A sequential opening mechanism is also conceivable:

The bonding mechanism here is identical to that described in the embodiment of FIG. 21 except that the surface, but not the (nano)particles, are functionalized.

FIG. 23 shows another embodiment of a multi-component system 1410 according to the invention, namely the alternative with functionalization of both the (nano)-particles as well as the (electrically)-conductive surface.

An adhesive is encapsulated in microcapsule K10. Microcapsule K20 contains (nano)-particles which are made of an (electrically) conductive material. The surface of the (nano)-particles is functionalized with terminal thiol groups, as is the (electrically)-conductive surface of the conductive path (i.e. the substrate B).

Here, too, both a parallel and a sequential opening mechanism are conceivable (cf. the above description in connection with the embodiment examples of FIG. 21 and FIG. 22).

FIG. 24 shows a further embodiment of a multi-component system 1510 according to the invention, namely the alternative of homogeneous functionalization of the (nano)-particles, as well as functionalization of the (electrically)-conductive surface with reactive functional groups, excluding thiol.

In this alternative, the microcapsule K10 is filled with adhesive. The microcapsule K20 with functionalized (nano)-particles. The (electrically) conductive surface is functionalized with the complementary functional group to the functional group of the (nano)-particles.

The opening mechanisms may take place in parallel or sequentially (see the foregoing description in connection with the embodiments of FIG. 21 and FIG. 22).

FIG. 25 shows a further embodiment example of a multi-component system 1610 according to the invention, namely the alternative of homogeneous functionalization of the (nano)-particles (substance S1), as well as the functionalization of the (electrically)-conductive surface (substrate B) with reactive functional groups.

In this embodiment example, the two surfaces (nano)-particles and (electrically)conductive surface of the substrate B are “electrically charged” (other word). In this case, the surfaces of the (nano)-particles have a negative charge. The surface of the (electrically) conductive surface (of the substrate B) exhibits a positive charge. In a further embodiment, the surfaces can also be oppositely charged. i.e. the (nano)-particles are positively charged and the (electrically)-conductive surface or the substrate B is negatively charged.

FIG. 26 shows another embodiment of a multi-component system 1710 according to the invention, namely the alternative of heterogeneous functionalization of the (nano)-particles (substance S1) for inter- and intra-crosslinking, as well as the functionalization of the (electrically)-conductive surface (substrate B).

In this embodiment, the (nano)particles are functionalized with two different functional groups. One functional group may be a terminal thiol R4, and the other functional group may be a carboxyl group R2. The (electrically) conductive surface is functionalized with the complementary functional group to the (nano)particles. In this embodiment, it would be terminal primary amine R1. Via the thiol group, the (nano)-particles are cross-linked with each other (by interlinking and/or intralinking).

FIG. 27 shows another embodiment of a multi-component system 1810 according to the invention, namely the alternative of functionalization of the microcapsules (substance S1).

The double microcapsules are prepared as described above. A further functional group, which is not responsible for binding the microcapsules to each other, binds to the (electrically) conductive surface (substrate B). In particular, a terminal thiol is to be used for this purpose, which selectively binds only to the metallic regions. Thus, the microcapsules can only be placed on the desired position (e.g.) metal surface, whereby there is no conductivity in the x-direction.

FIG. 28 shows a further embodiment of a multi-component system 1910 according to the invention, namely the alternative of functionalization of the (electrically) conductive surface (substrate B).

In this embodiment, the (electrically) conductive surface is functionalized with terminal thiol groups R1. At least one nano- and/or microcapsule has metal (nano)particles on its surface. By applying the microcapsule to the surface, the microcapsules of the metal (nano)particles selectively bind only to the surfaces having terminal thiol groups.

Instead of the metal (nano)-particles, the microcapsule can also be completely and/or partially coated with a metal surface.

FIG. 29 shows another embodiment of a multi-component system 2010 according to the invention, namely the alternative of functionalization of the microcapsule (substance S1) with a metal (nano) particle, a surface (substrate B).

Here, the surface of the microcapsule is provided with metallic nanoparticles. The (nano) and/or microcapsule may be functionalized by adding a chemical compound R3 with a terminal polymer, e.g. thiol compound. A second functional group of the polymer may be provided with another functional group R5. Thus, the thiol group R3 binds to the metal particles of the (nano) and/or microcapsule. The second functional group remains active and is available for further reactions. Thus, the microcapsule has a defined number of defined functional groups.

With a dithiol, the microcapsule can be functionalized as well as bound to the (electrically) conductive surface.

FIG. 30 and FIG. 31 each show a further embodiment of a multi-component system 2110 or 2210 according to the invention, namely alternatives for functionalization with thiol groups.

In order to bind the microcapsule K10, K20 to the (electrically) conductive surface (substrate B), the (nano)- and/or microcapsule K10, K20 is provided with a functional group R3 and the (electrically) conductive surface B is coated with the complementary functional group R1.

Only one dual-microcapsule may be provided with a functional group (cf. FIG. 30) or both microcapsules of the dual-microcapsule (cf. FIG. 31).

FIG. 32 to FIG. 34 each show a further embodiment according to the invention of a multi-component system 2310, 2410, 2510 and 2610 with multiple microcapsules (each suitable for connection to a substrate (not shown in FIG. 32 to FIG. 34).

The embodiments shown in FIGS. 32 to 34 may be manufactured in accordance with the manufacturing steps described above and below, and may have the corresponding features of the other systems accordingly.

The adhesive (glue) can be a one-component or two-component adhesive, whereby the adhesive can be in the same and/or separate portions of substance. It is also conceivable that even several components are provided correspondingly, if it is a multi-component adhesive.

FIG. 32 shows a multi-component system 2310 (viewed from left to right) with adhesive 1 in portion of substance K10 in the first capsule (far left), a single nanoparticle in the second capsule K20 and another capsule K10 with adhesive 1. An embodiment with several nanoparticles in one capsule is also conceivable.

FIG. 33 shows a multi-component system 2410 (viewed from left to right) with adhesive 1 in the first capsule K10 (far left), a second adhesive 2 in a capsule K30, and a single nanoparticle in the third capsule. Adhesive 1 and adhesive 2 may be components of a one-, two-component or multi-component adhesive.

FIG. 34 shows a multi-component system 2510 (viewed from left to right) with adhesive 2 in capsule K10, a second adhesive 1 in capsule K30, and a single nanoparticle in the third capsule K20. Adhesive 1 and adhesive 2 may be components of a two- or multi-component adhesive.

FIG. 35 shows a multi-component system 2610 (viewed from left to right) with adhesive 2 in first capsule K10 (far left), a single nanoparticle in second capsule K20, and a second adhesive 1 in third capsule K30. Adhesive 1 and adhesive 2 may be components of a one-, two-component or multi-component adhesive.

In principle, the above embodiments can be used to achieve (electrical) conductivity in a particular, predetermined or predeterminable direction as follows, wherein the conductivity is not limited to electrical conductivity but can also relate to the transmission of electrical conductivity, heat, data, etc:

(Nano)-particles functionalized with terminal thiol groups or magnetic particles or substrates and/or particles provided with functional groups are used. Electrostatic interactions can also be used.

The terminal functional groups can be provided with protective groups.

The nanoparticles and adhesive may be encapsulated, e.g. in microcapsules.

The following procedure can then be followed:

1. the microcapsules encapsulated with (nanoparticles) are brought together in an ambient medium (e.g. adhesive) as described in (our first patent).

2. via an activation mechanism (e.g. temperature) the microcapsules open and release the particles

3. via a chemical reaction, self-assembly, magnetism or some other mechanism, the particles arrange themselves in the desired direction.

4. particles are fixed by the ambient medium, which is also cured by heat, for example.

The opening of the microcapsules, the alignment of the particles and the curing of the ambient medium can take place in parallel or one after the other.

In another embodiment, for example, a structure can be made in three layers, namely surface (substrate), then first layer (e.g. ambient medium, e.g. adhesive, SAM coating etc.), then the second layer with microcapsules in which the nanoparticles are encapsulated and then the third layer (ambient medium e.g. adhesive).

Here, the surface or the substrate is coated first.

This is followed by a coating of functionalized capsules with nanoparticles that can be opened by a defined activation mechanism.

The terminal functional groups can be blocked with protective groups.

By a chemical reaction such as self-assembly, electro-static interactions, magnetism, etc. align the particles in the X-direction.

In all of the above-described embodiments, it is generally possible for multiple nanoparticles to be used in a single capsule.

For example, the singulation and placement of a single nanoparticle in a capsule can be achieved using technology from Nanoporetech (see Venkatesan, Bala Murali, and Rhashid Bashir, Nanopore Sensors for nucleic acid analysis, Nature Nanotechnology 6.10 (2011): 615. This method allows only a single DNA strand to pass through a singulation channel and can also be used to singulate nanoparticles.

### REFERENCE SIGN

10 Multiple component system
110 Multi-component system
210 Multi-component system
310 Multi-component system
410 Multi-component system
510 Multi-component system
610 Multi-component system
710 Multi-component system
810 Multi-component system
910 Multi-component system
1010 Multi-component system
1110 Multi-component system
1210 Multi-component system
1310 Multi-component system
1410 Multi-component system
1510 Multi-component system
1610 Multi-component system
1710 Multi-component system
1810 Multi-component system
1910 Multi-component system
2010 Multi-component system
2110 Multi-component system
2210 Multi-component system
2310 Multi-component system
2410 Multi-component system
2510 Multi-component system
2610 Multi-component system
B Substrate
C Core, Core
D Double microcapsule
K Capsule/capsule population
K1 Capsule 1/capsule population 1
K2 Capsule 2/Capsule population 2
K10 Capsule 10/Capsule population 10
K20 Capsule 20/Capsule population 20
K30 Capsule 30/Capsule population 30
Kn Capsule n/capsule population n
L Linker
L1 Linker
L2 Linker
L3 Linker
R functional group
R1 functional group
R2 functional group
R3 functional group
R4 functional group
R5 functional group
R21 functional group
Rn functional group n
S Capsule, Shell
S1 Substance/portion of substance
S3 Substance/portion of substance
St1 Step 1
St2 Step 2
St3 Step 3
St4 Step 4

1: A conductive multi-component system comprising:
at least one first substance, and
at least one substrate,
wherein
the at least one first substance is present in one or more portions of substance,
at least one first portion of substance is formed with at least one first functional group and is provided with a first linker and/or wherein the at least one substrate is formed with at least one second functional group and is provided with a second linker,
the at least one first functional group reacts via a predefined interaction with the at least one second functional group and/or the at least one substrate and binds them together, and/or wherein the at least one second functional group reacts via a predefined interaction with the at least one first functional group and/or the at least one first substance and binds them together, and
a portion of substance of the at least one first substance is present in the form of particles or in particles and is at least partially conductive.

2: The multi-component system according to claim 1, wherein a conductivity of the portion of substance is an electrical conductivity, a thermal conductivity, and/or a signal conductivity.

3: The multi-component system according to claim 1, wherein a distance of functional groups from the portion of substance and the at least one substrate is determined by the first linker and/or the second linker.

4: The multi-component system according to claim 1, wherein the at least one substrate is a circuit board, a printed circuit board, or a conductor path.

5: The multi-component system according to claim 1, wherein the at least one substrate is a second substance.

6: The multi-component system according to claim 5, wherein the second substance is present in one or more portions of substance.

7: The multi-component system according to claim 1, wherein the first linker is longer than the second linker or vice versa.

8: The multi-component system according to claim 1, wherein the at least one first functional group and the at least one second functional group are homogeneously or heterogeneously formed.

9: The multi-component system according to claim 1, wherein the portion of substance of the at least one first substance is arranged in a capsule or capsules.

10: The multi-component system according to claim 9, wherein the capsules have an identical size.

11: The multi-component system according to claim 1, wherein at least parts of the multi-component system can be activated, and an activation of the multi-component system is effected by at least one change of pressure, pH, UV radiation, osmosis, temperature, light intensity, and/or humidity.

12: The multi-component system according to claim 1, wherein the portion of substance of the at least one first substance is present in the form of a nanoparticle or nanoparticles, and wherein the nanoparticle or nanoparticles comprise a metallic material and have a surface coating.

13: The multi-component system according to claim 12, wherein the surface coating and/or a surface functionalization are formed at least partially by terminal functional groups and/or linkers, which bind selectively to metallic surfaces, SAM surfaces, and/or stabilizers.

14: The multi-component system according to claim 1, wherein the portion of substance of the at least one first substance is present in the form of nanoparticles, and the nanoparticles are stabilized by a matrix.

15: The multi-component system according to claim 1, wherein the portion of substance of the at least one first substance is present in the form of nanoparticles, and the nanoparticles each comprise at least one shell and at least one core.

16: The multi-component system according to claim 1, wherein the portion of substance of the at least one first substance is present in the form of nanoparticles, and the nanoparticles are incorporated in a particle, the particle comprising at least one core and at least one shell, wherein the at least one core contains at least one nanoparticle.

17: The multi-component system according to claim 1, wherein the portion of substance of the at least one first substance is present in the form of nanoparticles, and at least a portion of the nanoparticles is arranged in a first capsule and a second portion of substance is provided which is also arranged in at least one second capsule, wherein both the first capsule and the at least one second capsule can each be activated.

18: A method of making a multi-component conductive system comprising at least one first substance and at least one substrate, wherein the first substance is present in one or more portions of substance, the method comprising:
forming at least one first portion of substance with at least one first functional group and provided with a first linker, and/or forming the at least one substrate with at least one second functional group and provided with a second linker, and reacting the at least one first functional group via a predefined interaction with the at least one second functional group and/or the at least one substrate, to produce a conductive compound; and/or reacting the at least one second functional group via a predefined interaction with the at least one first functional group and/or the at least one first substance to produce a conductive compound.

19: The method according to claim 18, wherein the at least one first portion of substance is formed with at least one third functional group and is provided with a third linker,
wherein the at least one third functional group each has at least one protective group, so that only correspondingly functionalized portions of substance of the at least one first substance can bind to portions of substance of the at least one first substance, and wherein the method further comprises at least removing protective groups that are initially present, only when the at least one first portion of substance are to be linked to each other by the at least one third functional group.

20: The method according to claim 18, wherein the multi-component system comprises a portion of the at least one first substance in the form of particles or in particles and is at least partially conductive.
